(19) United States
(12) Patent Application Publication
(10) Pub. No.: US 2026/0371790 A1
(43) Pub. Date: Nov. 19, 2026

(54) PLASMA DAMAGE-FREE PIXELATION OF OPTOELECTRONIC DEVICES

(71) Applicant: ams-OSRAM International GmbH, Regensburg (DE)

(72) Inventor: Florian Voegl, Regensburg (DE)

(21) Appl. No.: 19/487,916

(22) PCT Filed: May 23, 2024
(86) PCT No.: PCT/EP2024/064304

§ 371 Date: Nov. 25, 2025

(30) Foreign Application Priority Data
May 25, 2023 (DE) 10 2023 113 824.3

(51) Int. Cl. H10H 20/82; H10H 20/01; H10H 20/825; H10H 20/841

(52) U.S. Cl. CPC H10H 20/82; H10H 20/0137; H10H 20/017; H10H 20/034; H10H 20/825; H10H 20/841

(57) ABSTRACT

In an embodiment a method includes plasma etching a semiconductor layer stack such that a first portion of the semiconductor layer stack is retained and a second portion of the semiconductor layer stack adjacent to the first portion is removed, thereby forming a recess exposing a side surface of at least an active region of the first portion, providing a structured material layer on the first portion covering at least one first sub portion of the first portion and leaving a second sub portion of the first portion adjacent to the at least one first sub portion exposed, wherein the at least one first sub portion is defined by an virtual shell surface extending through the semiconductor layer stack and including a contour of the structured material layer adjacent to the at least one first sub portion and wet chemical anisotropic etching the first portion such that the second sub portion is removed until an imaginary shell surface and such that the at least one first sub portion is retained.

### CROSS-REFERENCE TO RELATED APPLICATIONS

This patent application is a national phase filing under section 371 of PCT/EP2024/064304, filed May 23, 2024, which claims the priority of German patent application no. 10 2023 113 824.3, filed May 25, 2023, each of which is incorporated herein by reference in its entirety.

### TECHNICAL FIELD

The present invention concerns a method for manufacturing an optoelectronic device comprising a plasma damage free pixelation of the optoelectronic device as well as an optoelectronic device.

### BACKGROUND

In order to increase the external quantum efficiency (EQE) of for example μ-LEDs, or more general light emitting nanostructures, one can engineer the geometry, shape and surroundings (passivation, reflective mirror, . . . ) of the μ-LEDs in a way that the light extraction efficiency (LEE) in a specific solid angle is maximized. Apart from the LEE the internal quantum efficiency (IQE) is as important, where a main loss factor originates from non-radiative recombination of charge carriers within the μ-LED.

Plasma etching is a common and standard process for pixel etching (etching through the active region and physical separation of individual pixels), but introduces plasma damage to the surface and underlying layers dependent on the specific process and parameters used. Plasma damage in this case means the creation of defect centres in the crystal lattice caused by Ion bombardment. Especially for small pixels such as for the case of μ-LEDs with a high surface-to-volume ratio, in particular a high ratio of the exposed active region surface on the pixel's sidewall vs. the total active region volume, this is a major challenge. Defects created on the surface and below of the active region—which is exposed during and after pixel etching by means of plasma etching—act as non-radiative recombination channels and dramatically reduce the IQE of the μ-LED leading to a bad overall performance.

The same applies to laser devices such as vertical-cavity surface-emitting lasers (VCSEL) and edge-emitting lasers. They also face a high surface-to-volume ratio. In addition to μ-LEDs, some of the etched side surfaces of the lasers are within the light path of the light to be emitted and therefor have to be optically perfect. This can mean that the etched side surface(s) need to comprise a lower/no absorption resulting in higher COD-levels.

A common approach to remove plasma damage from side surfaces of μ-LEDs is a subsequent so-called defect etching step, where defects are removed while not creating new defects. Therefore, usually wet chemistry is used, mostly aqueous KOH. The plasma etching however can create defects on the side surfaces and also below the side surfaces of the active region which can extend further into the μ-LED as can be removed by such a subsequent surface treatment using for example KOH.

### SUMMARY

Embodiments of the present application provide a method for manufacturing an optoelectronic device and μ-LED in particular, by which a particularly defect free pixelation of the optoelectronic device can be achieved. Further embodiments provide a respective optoelectronic device and μ-LED in particular with a high IQE.

The KOH wet etching behaviour of GaN is highly anisotropic due to different etch rates in different crystallographic directions. In case of a semiconductor layer stack of for example a GaN material system, which is grown in c-plane and thus vertical direction, this means that the KOH etching propagates starting from a trigger point in a lateral direction/perpendicular to the vertical direction through the semiconductor layer stack but not in the vertical direction.

Depending on the depth of the trigger point such as for example a recess or gap in the semiconductor layer stack the KOH etching laterally etches the whole layer stack but not deeper than the depth of the trigger point and laterally removes the material of the semiconductor layer stack. At the same time, a material layer such as for example a conductive material layer of indium tin oxide or a dielectric material layer arranged on the semiconductor layer stack creates a self-limiting virtual barrier for the lateral etching, wherein the virtual barrier is defined by the shell surface of a volume that is formed by a projection of the conductive material layer perpendicular into the semiconductor layer stack. The inventor now turns this behaviour to his advantage by using it to not only surface treat pixelated optoelectronic devices but to etch optoelectronic devices out of a semiconductor layer stack.

In the common approach of pixelating optoelectronic devices such as μ-LEDs out of a semiconductor layer stack by means of plasma etching and then surface treating the side surfaces of the pixelated optoelectronic devices, the optoelectronic devices still tend to comprise plasma damage in the vicinity of the side surfaces even after surface treatment. This is as the plasma etching injects components of the plasma into the optoelectronic devices with a depth that that is not being removed by means of the subsequent surface treatment resulting in a contaminated region comprising plasma damage even in the final optoelectronic device. The inventor found that the step of plasma etching can however be conducted at such a distance to the later optoelectronic devices such that plasma damage and thus a contaminated region of the material of the semiconductor layer stack comprising plasma damage only occurs at a sufficient distance to the later optoelectronic device. Thus, when the plasma etching is only used to generate a recess at a sufficient distance to the later optoelectronic device with a desired depth to later pixelate the optoelectronic devices by means of the anisotropic etching behaviour of for example KOH but not a step of plasma etching, it can be ensured that the optoelectronic devices itself do not comprise plasma damage at all. The self-limiting behaviour when arranging a material layer such as for example a conductive material layer on respective portions of the semiconductor layer stack can thereby be used to define the position of the optoelectronic devices to be etched.

Hence the concept of the embodiments of the present invention is to: plasma etch a recess into a semiconductor layer stack at a sufficient distance to optoelectronic devices to be etched out of the semiconductor layer stack and with a sufficient depth relating to the desired height of the optoelectronic devices; Providing a structured material layer, in particular conductive material layer, such that portions of the material layer cover portions of the semiconductor layer stack to be retained and later forming the optoelectronic devices; and wet chemical anisotropic etching the semiconductor layer stack staring from the recess in lateral but not vertical direction such that the semiconductor material around the optoelectronic devices but not the optoelectronic devices themself are removed. The plasma etching thus acts only to provide a trigger in form of for example creating a recess in the semiconductor layer stack and the pixelation itself results from wet chemical anisotropic etching in combination with a respective arrangement of a structured material layer on top of the semiconductor layer stack. The resulting optoelectronic devices do not suffer from possible plasma damage within their structure and a surface treatment of side surfaces of the optoelectronic devices becomes redundant.

In a first embodiment, a method for manufacturing an optoelectronic device is provided. The method comprises the steps:
Providing a semiconductor layer stack of at least a first layer of a first conductivity type, a second layer of a second conductivity type as well as an active region between the first and second layer;
Plasma etching into the semiconductor layer stack such that a first portion of the semiconductor layer stack is retained and a second portion of the semiconductor layer stack adjacent to the first portion is removed, thereby forming a recess exposing a side surface of at least the active region of the first portion;
Providing a structured material layer, in particular structured conductive material layer, on the first portion covering at least a first sub portion of the first portion and leaving a second sub portion of the first portion adjacent to the at least one first sub portion exposed, wherein the at least one first sub portion is defined by an virtual shell surface extending through the semiconductor layer stack and comprising a contour of the structured material layer adjacent to the at least one first sub portion; and
Providing a wet etchant into at least the recess, thereby conducting a wet chemical anisotropic etching of the first portion such that the second sub portion is removed until the imaginary shell surface and such that the at least one first sub portion is retained.

The step of plasma etching the semiconductor layer stack such that at least a first portion of the semiconductor layer stack is retained and at least a second portion of the semiconductor layer stack adjacent to the first portion is removed can for example be a conventional process comprising conventional stepper lithography and plasma etching processes. In particular the first portion can comprise later optoelectronic device(s)/pixel(s) separated out of the semiconductor layer stack.

In some embodiments, the second sub portion is adjacent to the recess. Thus, by means of the wet chemical anisotropic etching portion(s) of the semiconductor layer stack, adjacent to the plasma etched recess are being removed. In particular the portion directly adjacent to the recess is in a desired embodiment to be removed, as in particular this portion tends to comprise plasma damage due to the plasma etching of the recess.

In some embodiments, the step of plasma etching into the semiconductor layer stack comprises injecting components of the plasma into the first portion adjacent to the recess forming a contaminated region of the semiconductor layer stack. This contaminated region is in particular spaced apart from the at least one first sub portion and does not overlap with the same. Hence it can be ensured that the at least one first sub portion is free of plasma damage.

In some embodiments, the resulting optoelectronic devices are light emitting elements such as light emitting diodes (LED) and in particular μ-LEDs, vertical-cavity surface-emitting lasers (VCSEL), or edge-emitting lasers. μ-LEDs can in particular be small LEDs with edge lengths smaller than 50 μm, smaller than 30 μm, smaller than 10 μm or in particular smaller than 5 μm or in particular with edge lengths substantially equal to 1 μm. The optoelectronic devices can however also be photodiodes with a respective size or other light emitting or light detecting components comprising a semiconductor material with sizes in the above-mentioned ranges.

In some embodiments, a distance between the recess and the at least one first sub portion is at least 10 nm, at least 50 nm or at least 100 nm. Such a distance can in particular be enough to just ensure that the first sub portion is far enough distanced from the plasma etched recess such that the first sub portion does not comprise any plasma damage due to the plasma etching of the recess at all.

In some embodiments, the wet etchant comprises at least one of potassium hydroxide (KOH), phosphoric acid (H₃PO₄), tetramethylammonium hydroxide (TMAH), peroxymonosulfuric acid (H₂SO₅), ammonium hydroxide (NH₄OH), ammonium monosulfide ([NH₄]₂S), hydrogen chloride (HCl), and combinations thereof.

In some embodiments, the method further comprises a step of providing a material layer, in particular conductive material layer or dielectric material stack, on the semiconductor layer stack. In this case the step of providing the structured material layer comprises a structuring of the material layer such that the structured material layer covers the at least one first sub portion and leaves the second sub portion exposed. Hence the structured material layer can result from directly proving the structured material layer on the semiconductor layer stack in a structured way but can also result from a structuring of a prearranged material layer on the semiconductor layer stack.

In some embodiments, the step of providing the material layer is conducted before the step of plasma etching into the semiconductor layer stack. The material layer can then for example be pre-structured by means of the step of plasma etching into the semiconductor layer stack and a structuring of the material layer to receive the structured material layer can result from a later structuring of the same.

In some embodiments, the structured material layer acts as a hardmask arranged on the semiconductor layer stack which influences the self-limiting anisotropic wet etching process. The structured material layer can in particular comprise a conductive material to provide a later top contact element of the optoelectronic device(s). For example the structured material layer can comprise a transparent conductive oxide (TCO) such as indium tin oxide (ITO), indium zinc oxide (IZO), or indium gallium zinc oxide (IGZO). However also other dielectric or metal materials such as for example metallic reflectors such as for example silver are possible to be used for the structured material layer. In addition, it is also possible to form the structured material layer of any other material that influences the self-limiting anisotropic wet etching process in the described way which is than for example after the step of anisotropic wet etching removed and another top contact element is later provided on the optoelectronic device(s).

In some embodiments, the method further comprises a step of providing a first mask in particular structured mask on the semiconductor layer stack or on the material layer covering the first portion and exposing the second portion for plasma etching the semiconductor layer stack such that the first portion of the semiconductor layer stack is retained and the second portion of the semiconductor layer stack adjacent to the first portion is removed forming a recess. The first mask can for example be a lithographic etch mask such as for example a photoresist being structured, baked and developed such that it covers the first portion of the semiconductor layer stack and exposes the second portion of the semiconductor layer stack. The mask can for example have different pitches, sizes and shapes (round shaped, rectangular, square, hexagonal, . . . ).

In some embodiments, the method further comprises a step of providing a second mask in particular structured mask on the semiconductor layer stack or on the material layer covering the at least one first sub portion and exposing the second sub portion for structuring the material layer or providing the structured material layer. In case of structuring the material layer the second mask covers the at least one first sub portion and exposes the second sub portion to remove the material layer on the second sub portion. In case of providing the structured material layer on the semiconductor layer stack layer the second mask covers the second sub portion and exposes the at least one first sub portion to be able to provide the structured material layer on the at least one first sub portion. The second mask can for example be a lithographic etch mask such as for example a photoresist being structured, baked and developed such that it covers the respective sub portion of the semiconductor layer stack and exposes the other sub portion of the semiconductor layer stack. The mask can for example have different pitches, sizes and shapes (round shaped, rectangular, square, hexagonal, . . . ).

In some embodiments the method further comprises a step of chemically and/or physically modifying the side surfaces of the recess as well as the rest of the semiconductor layer stack to enable or favour a subsequent step of anisotropic wet etching the semiconductor layer stack. Such a step can also be conducted simultaneously to the step of structuring the material layer or result from the same.

In some embodiments, the semiconductor layer stack and in particular the first and second layer as well as the active region are of a nitride based material system. For example the semiconductor layer stack and in particular the first and second layer as well as the active region are of a gallium nitride (GaN) semiconductor material system. For example in case of nitride based semiconductor material systems, the creation of non-radiative recombination centres due to plasma etching can be very critical. However, the semiconductor layer stack can be of other different Epi structure as well.

In some embodiments, the at least one first sub portion comprises a rectangular cross section when seen in side and/or top view. In particular when seen in side view the at least one first sub portion comprises a rectangular cross section due to the virtual shell surface defining the at least one first sub portion starting from the contour of the structured material layer adjacent to a top surface of the semiconductor layer stack and extending perpendicular to the top surface into the semiconductor layer stack. When seen in a top view the at least one first sub portion can also comprise a rectangular cross section, however any other shape is also possible depending on the shape of the structured material layer arranged on the first sub portion. For example the first sub portion can also comprise a square, rectangular, round, ellipsoid, hexagonal or any other polygonal cross section when seen in top view.

In some embodiments, the method further comprises a step of separating the optoelectronic device in particular by detaching it from a growth substrate on which the semiconductor layer stack is grown or by detaching it from a residue portion of the first layer which has not been pixelated by means of the etching processes. Such a separated optoelectronic device in particular comprises the first sub portion of the semiconductor layer stack comprising at least a portion of the first layer, the second layer and the active region arranged between the first and second layer as well as optionally a portion of the structured material layer arranged on the first sub portion and forming a top contact element.

By means of aforementioned steps not only one optoelectronic device can be manufactured but a plurality of optoelectronic devices can be manufactured by retaining a plurality of first sub portions of the semiconductor layer stack and removing respective second portion(s) and second sub portion(s) adjacent to the first portion(s) and between the first sub portions resulting in a plurality of etched first sub portions each forming an optoelectronic device.

In another embodiment, an optoelectronic device, in particular an optoelectronic device is manufactured in accordance with some of aforementioned embodiments. The optoelectronic device comprises a semiconductor layer stack of at least a first layer of a first conductivity type, a second layer of a second conductivity type as well as an active region between the first and second layer. The optoelectronic device further comprises a top contact element arranged on a top surface of the semiconductor layer stack opposite a bottom surface of the semiconductor layer stack. Side surfaces of the semiconductor layer stack connecting the top surface and the bottom surface are thereby substantially perpendicular with respect to the top surface. In addition, the side surfaces comprise a surface roughness of less than 10 nm and in particular of less than. Further the semiconductor layer stack comprises along its side surfaces a defect density that causes a current density along the side surfaces of less than or in in the order of 1e⁻⁴ A/cm² when applying a potential difference of −5V between the top and bottom contact element or that causes a current density along the side surfaces of less than or in in the order of 1e⁻⁴ A/cm² when applying a potential difference of +1V between the top and bottom contact element.

In some embodiments, the semiconductor layer stack and in particular the first and second layer as well as the active region are of a nitride based semiconductor material system such as for example a GaN material system.

In some embodiments, the top contact element comprises a transparent conductive oxide, such as for example ITO, IZO or IGZO.

In some embodiments, the top contact element comprises a reflective metal mirror, such as for example silver.

In some embodiments, the top contact element directly adjoins the top surface and side surfaces of the top contact element enclose an angle with the top surface of smaller than or equal to 90°. This can in particular mean that the top contact element on the top surface does not comprise an underetching and thus does not comprise regions distant from the top surface which laterally protrude regions adjacent to the top surface.

The proposed solution works for any nitride based μ-LED pixel shapes or more general light emitting nanostructures etched by plasma with exposed active regions. Also, for laser devices like VCSELs or edge-emitting lasers the solution is very promising, as it could further be used to improve etched facets not only for electrical, but also for optical reasons.

### BRIEF DESCRIPTION OF THE DRAWINGS

Further aspects and embodiments in accordance with the proposed principle will become apparent in relation to the various embodiments and examples described in detail in connection with the accompanying drawings in which:

FIG. 1A to 1C shows steps of a method for manufacturing an optoelectronic device;

FIGS. 2A to 9B shows steps of a method for manufacturing an optoelectronic device;

FIG. 10 shows a top view of a further step of a method for manufacturing an optoelectronic device;

FIG. 11 shows a top view of a further step of a method for manufacturing an optoelectronic device; and

FIG. 12 shows two embodiments of a structured material layer on top of a semiconductor layer stack.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

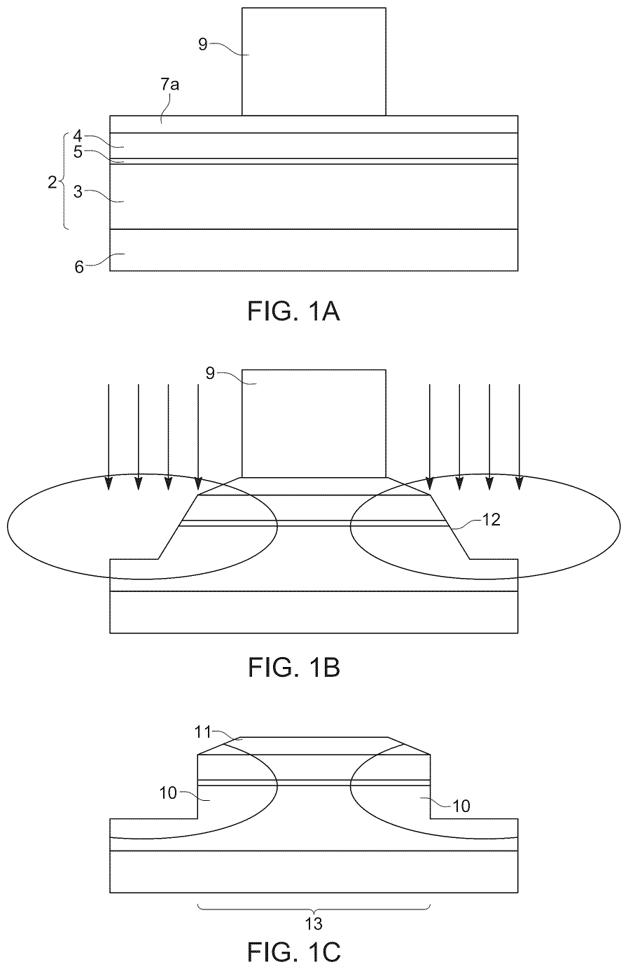

FIGS. 1A to 1C show steps of a method for manufacturing an optoelectronic device not according to the proposed principle. As shown in FIG. 1A, in a first step, a semiconductor layer stack 2 of at least a first layer 3 of a first conductivity type, a second layer 4 of a second conductivity type as well as an active region 5 between the first and second layer 3, 4 is provided. The semiconductor layer stack 2 is arranged on a growth substrate 6 and a conductive material layer za of for example ITO is arranged on the semiconductor layer stack 2. The semiconductor layer stack 2 is in a subsequent step pixelated by means of plasma etching as shown in FIG. 1B resulting in etched side surfaces 12 of the pixelated portion. The plasma etching introduces damage on the side surface 12 as well as below the side surfaces 12 forming a plasma contaminated region 10. This in particular in the active region 5 is a major problem, since it creates non-radiative recombination channels for charge carriers along the side surfaces 12 leading to a low EQE of the final optoelectronic device. This effect is less relevant for large structures, but is very important to be dealt with for small pixels with a high surface/volume ratio such as for example u-LEDs.

To reduce the plasma damage along the side surfaces 12, a surface treatment using KOH is conducted in a subsequent step to remove the damages introduced by the plasma etching resulting in the structure shown in FIG. 1C. The etching of the KOH due to its anisotropic behaviour removes the mesa structure generated by means of the plasma etching and stops due to the conductive material layer 7a being of for example of ITO and acting as an etch stop. As however indicted by the contaminated region 10 the pixelation by means of plasma etching results in the optoelectronic device still comprising plasma damage even along and below its surface treated side surfaces leading to a low EQE of the final optoelectronic device.

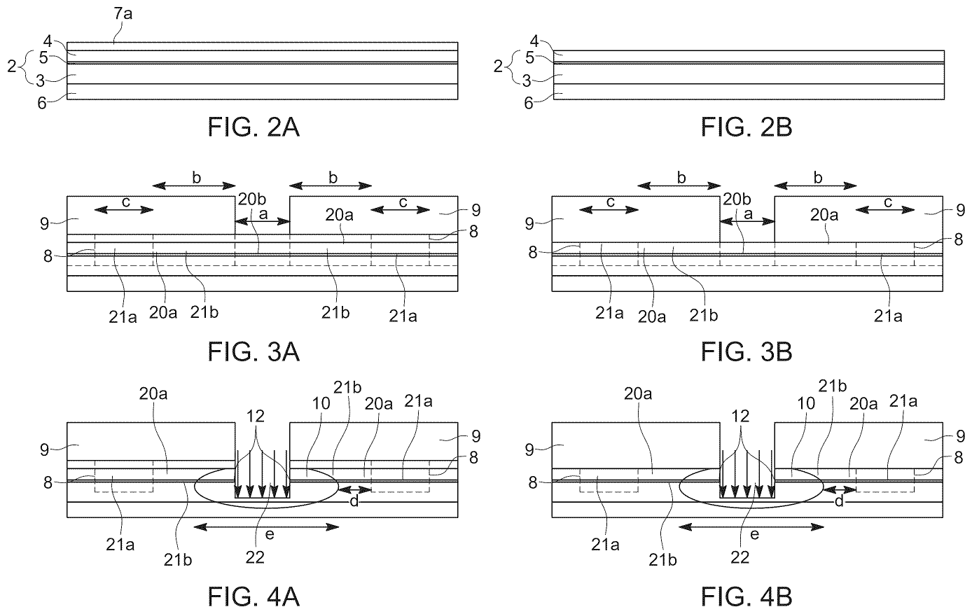

To counteract this problem the inventor proposes another approach of pixelation which is exemplarily shown in FIGS. 2A to 9B. These show exemplary steps of a method for manufacturing an optoelectronic device. In particular Figures xA show a first alternative of exemplary steps of a method for manufacturing an optoelectronic device according to some embodiments whereas Figures xB show a second alternative of exemplary steps of a method for manufacturing an optoelectronic device according to some other embodiments with x being meant as a variable counting from 2 to 9. The two embodiments in particular differ in the way and point of time of a structured material layer 7b being provided on the semiconductor layer stack 2.

As shown in FIGS. 2A and 2B in a first step, a semiconductor layer stack 2 of at least a first layer 3 of a first conductivity type, a second layer 4 of a second conductivity type as well as an active region 5 between the first and second layer 3, 4 is provided. The semiconductor layer stack 2 is arranged on a growth substrate 6. As shown in FIG. 2A a material layer 7a of for example ITO is arranged on the semiconductor layer stack 2, whereas as an alternative, FIG. 2B shows the step without providing such a material layer.

As shown in FIGS. 3A and 3B in a following step, a first mask 9 is provided on the material layer 7a and the semiconductor layer stack 2 respectively. The first mask 9 covers a first portion 20a of the semiconductor layer stack 2 and exposes a second portion 20b of the semiconductor layer stack 2 and the material layer 7a respectively. The deposition of the first mask 9 serves to prepare for a plasma etching process in order to expose areas that are to be removed by means of the plasma etching process. The first mask 9 is thereby provided on the material layer za and the semiconductor layer stack 2 respectively such that it covers a first portion 20a and exposes a second portion 20b of the semiconductor layer stack 2 and the material layer 7a respectively. The second portion 20b thereby, at least in the shown side view, comprises an area with a first width a. Further the first mask 9 is provided on the material layer 7a and the semiconductor layer stack 2 respectively such that the second portion 20b exposed by the first mask 9 is distant from first sub portions 21a which later each form an optoelectronic device (indicated by the dotted line 8) with a first distance b. The first distance b is chosen such that a potentially contaminated region of the semiconductor layer stack 2 caused by a following plasma etching of the second region 20b is distant from the first sub portion 21a and thus from the later formed optoelectronic device. The first sub portion 21a and thus the later formed optoelectronic device thereby, at least in the shown side view, comprises an area with a second width b resulting in a respective edge length of the later formed optoelectronic device. In particular first width a can be in the range from 0.5 μm to 100 μm and even more particularly in the range from 1 μm to 5 μm. The first distance b can in particular can be in the range from 10 nm to 5 μm and even more particularly in the range from 50 nm to 500 nm. And the second width c can be in the range from 500 nm to 50 μm and even more particularly in the range from 1 μm to 5 μm.

FIGS. 4A and 4B show the step of plasma etching into the semiconductor layer stack 2 removing the second portion 20b and forming recess 22. The recess 22 comprises a depth such that it exposes side surfaces 12 of the first portion 20a each exposing a portion of the first layer 3, the second layer 4 and the active region 5. The depth of the recess 22 is however chosen to not extend through the whole layer stack 2 but only through the second layer 4, the active region 5 and part of the first layer 2. By this a bottom portion of the first layer 3 is still connected and holds together the first portions 20a on both sides of the recess 22 in addition to the growth substrate 6. By means of the depth of the recess 22 the size of the later formed optoelectronic components in terms of height can be set, as the following wet etching step for pixelating the optoelectronic devices is chosen such that it in an anisotropic manner only etches latterly through the semiconductor layer stack 2 starting from the recess 22.

The step of plasma etching into the semiconductor layer stack as a side effect comprises an injection of components of the plasma into the first portion 20a adjacent to the recess 22 forming a contaminated region 10. Regarding the size of the contaminated region 10, indicated by the third width e in FIGS. 4A and 4B, the first distance b has in advance be chosen such that between the contaminated region 10 and the first sub portions 21a still a second distance d is present after plasma etching to make sure the first sub portions 21a and the contaminated region 10 do not overlap. The second distance d can in particular be in the range from 0 nm to 100 μm and even more particularly in the range from 0 nm to 1 μm.

FIGS. 5A and 5B show the resulting structure after removal of the first mask 9, with the recess 22 in the semiconductor layer stack 2 and the contaminated region 10 surrounding the recess 22 but being distant to the first sub portions 21a.

FIGS. 6A and 6B show a subsequent step of arranging a second mask 9 on the material layer za or the semiconductor layer stack 2 respectively. In case of FIG. 5A the second mask 9 is provided on the material layer 7a such that it covers first sub portions 21a and exposes second sub portions of the first portion 20a of the semiconductor layer stack 2. The deposition of the second mask 9 serves to prepare for a structuring of the material layer 7a in order to expose the second sub portions 21b of the semiconductor layer stack 2 and retain a structured material layer 7b on the first sub portions 21a of the semiconductor layer stack 2. On the other hand, in case of FIG. 5B the second mask 9 is provided on the semiconductor layer stack 2 such that it exposes the first sub portions of the first portion 20a of the semiconductor layer stack 2 and covers the rest of the semiconductor layer stack 2. The deposition of the second mask 9 serves to prepare for providing structured material layer 7a on the first sub portions 21a of the semiconductor layer stack 2.

Hence in a subsequent step as shown in FIGS. 7A and 7B the material layer 7a is structured via for example wet chemical etching and the structured material layer 7b is provided respectively in particular without adding a further/new damage to the semiconductor layer stack 2. The second mask 9 as well as possible residues of the material layer on the second mask 9 are then removed resulting in the structure shown in FIG. 8A with the structured material layer 7b being arranged on the first sub portions 21a of the semiconductor layer stack 2. In an additional optional step, the resulting side surfaces 12 of the recess 22 as well as the rest of the semiconductor layer stack 2 can be chemically and/or physically modified to enable or favour a subsequent step of anisotropic wet etching the semiconductor layer stack 2. Such a step can also be conducted simultaneously to the step of structuring the material layer 7a or result from the same.

The first sub portions 21a are in particular be defined by a virtual shell surface 8 extending through the semiconductor layer stack 2 down to the depth of the recess and comprising a contour of the portions of the structured material layer 7b adjacent to respective first sub portion 21a on which they are arranged. In particular the shell surface 8 relates to a projection of the portions of the structured material layer 7b arranged on the first sub portions 21a in a vertical direction into the semiconductor layer stack or said in other words relates to a vertical extension of the portions of the structured material layer 7b arranged on the first sub portions 21a into the semiconductor layer stack. This shell surface is indicated by the dotted line and indicates the size and position of the later formed optoelectronic device and indicates the etching border for the self-limiting anisotropic wet etching step which is conducted in a following step as shown in FIG. 9A.

FIG. 9A shows a following step of anisotropic wet etching the semiconductor layer stack 2 starting from the recess 22. Therefore, a wet etchant as for example KOH is provided at least in the recess 22. The etching direction of the anisotropic wet etching is indicated by the arrows showing that only a lateral etching takes place. Hence starting from the recess, the material of the semiconductor layer stack 2 and in particular the second sub portions 21b are removed by means of the wet etchant. The material of the semiconductor layer stack 2 is chosen and chemically and/or physically prepared in a way that allows lateral etching with wet chemistry even though when there is no structured material layer 7b present on the top surface 15. However, the etching stops in lateral direction when a structured material layer 7b is present on the top surface 15. The etchant, the material system of the semiconductor layer stack 2, the material of the structured material layer 7b as well as the process parameters (for example temperature, time, and etchant concentration) is thereby chosen such that the etching stops at the virtual shell surface 8 due to the structured material layer 7b being arranged on the first sub-portions 21a. The anisotropic wet etching can therefore be called a self-limiting process, as it etches/removes the semiconductor layer stack in lateral direction but stops automatically at the virtual shell surfaces 8. As shown in the sequence of FIG. 9A from the top to the bottom, the anisotropic wet etching propagates starting from the recess 22 through the semiconductor material and over time removes any material of the semiconductor layer stack adjacent to the shell surfaces 8 and not being covered by the structured material layer 7b however only in lateral direction and not deeper than the depth of the recess 22 thereby exposing the first sub portions 21a of the semiconductor layer stack each forming an optoelectronic device 1.

FIG. 8B shows a further example of a structure according to some embodiments which can be manufacture using the steps shown in FIGS. 2A to 7B. In contrast to the structure shown in FIG. 8A the recess 22 is not arranged between first sub portions 21a but along an edge of the semiconductor layer stack 2 adjacent to a plurality of first sub portions 21a each with a portion of the structured material layer 7b being arranged on the first sub portions 21a of the semiconductor layer stack 2.

FIG. 9B shows a following step of anisotropic wet etching the semiconductor layer stack 2 starting from the recess 22. Therefore, a wet etchant as for example KOH is provided at least in the recess 22. The etching direction of the anisotropic wet etching is indicated by the arrows showing that only a lateral etching takes place. Hence starting from the recess, the material of the semiconductor layer stack 2 and in particular the second sub portions 21b are removed by means of the wet etchant. The etchant, the material system of the semiconductor layer stack 2, the material of the structured material layer 7b as well as the process parameters (for example temperature, time, and etchant concentration) is chosen such that the etching stops at the virtual shell surface 8 due to the structured material layer 7b being arranged on the first sub-portions 21a. As shown in the sequence of FIG. 9B from the top to the bottom, the anisotropic wet etching propagates starting from the recess 22 through the semiconductor material and over time removes any material of the semiconductor layer stack adjacent to the shell surfaces 8 and not being covered by the structured material layer 7b however only in lateral direction and not deeper than the depth of the recess 22 thereby exposing the first sub portions 21a of the semiconductor layer stack each forming an optoelectronic device 1.

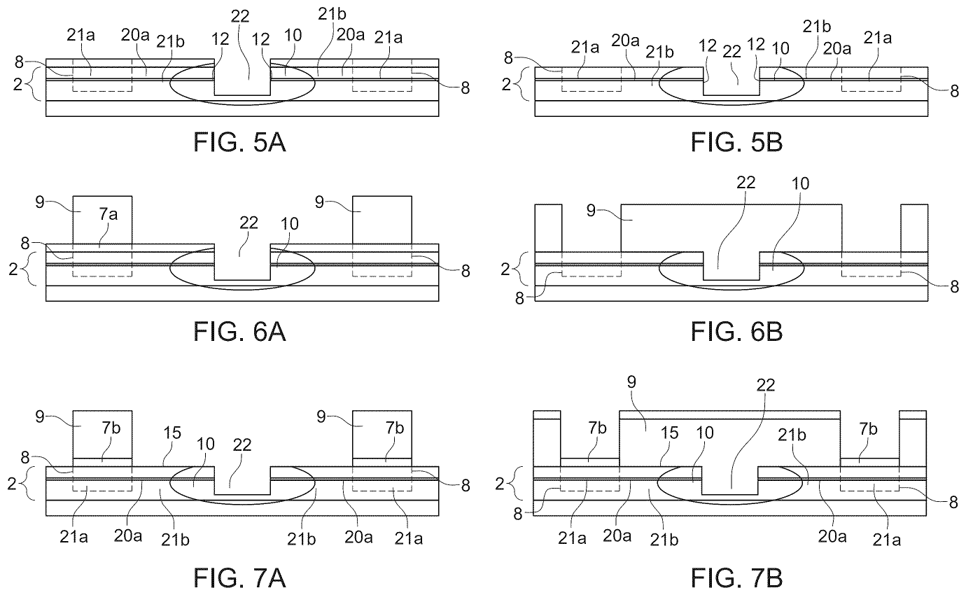

FIG. 10 shows a respective top view of the step of anisotropic wet etching the semiconductor layer stack 2 starting from the recess 22 as shown in FIG. 9B. Here to, it is shown a sequence from the top to the bottom, of the anisotropic wet etching propagating starting from the recess 22 through the semiconductor material and over time removing any material of the semiconductor layer stack adjacent to the shell surfaces 8 not being covered by the structured material layer 7b. By this the first sub portions 21a of the semiconductor layer stack 2 are exposed each forming an optoelectronic device 1.

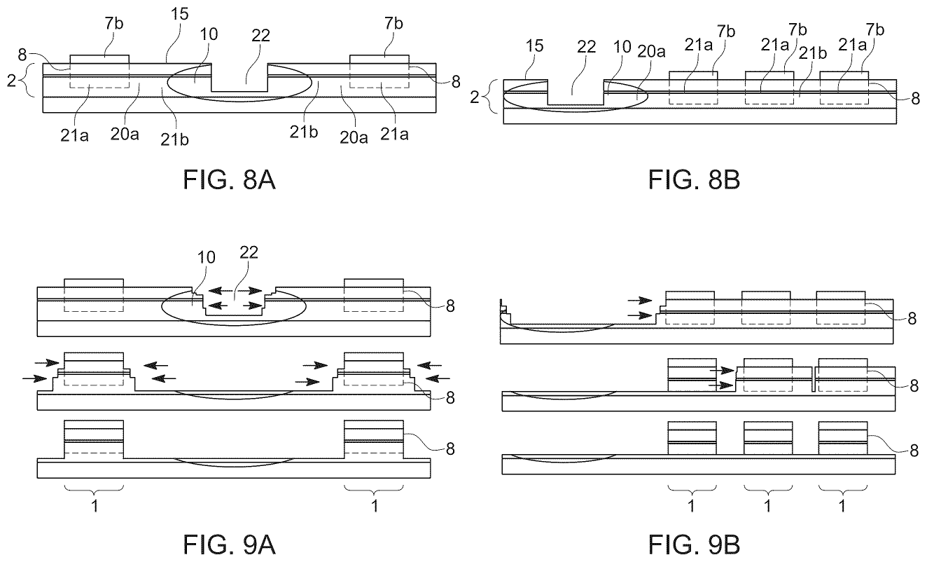

As shown in the FIGS. 9B and 10, the recess 22 can be arranged at a great distance from the first sub portions 21a to ensure that the later formed optoelectronic devices 1 do not comprise any plasma damage along their side surfaces. The arrangement of the recess 22 as shown in FIGS. 9B and 10 along one of the edges of the semiconductor layer stack 2 is however understood to be exemplary and can vary in any way as long as the distance to all of the first sub portions 21a is large enough to not comprise any plasma damage. For example, for speeding up the anisotropic wet etching, the recess 22 can be several recesses 22 arranged along all side surfaces or opposing side surface of the semiconductor layer stack 2 or, as shown in top view in FIG. 11 inbetween the first sub portions 21a with each enough distance to the contaminated regions 10 resulting from the plasma etching.

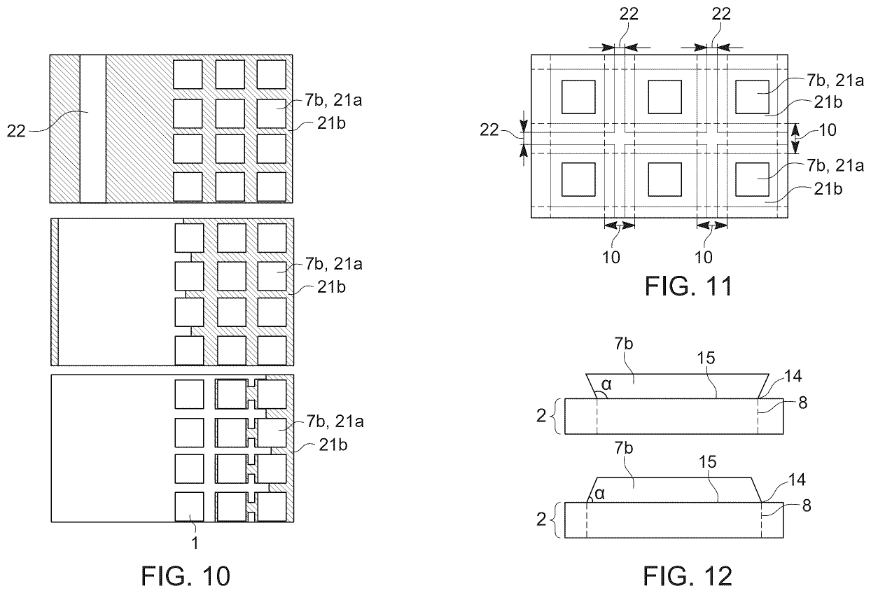

FIG. 12 shows two embodiments of a structured material layer 7b on top of a semiconductor layer stack 2. By this it shall in particular be indicated how the shell surface 8 is being defined extending from the structured material layer 7b into the semiconductor layer stack. In addition FIG. 12 shows in its lower image the preferred embodiment of how the structured material layer 7b/top contact element is in a preferred way to be formed on the first sub portion 21a/optoelectronic device 1.

The first sub portions 21a are in particular be defined by a virtual shell surface 8 extending through the semiconductor layer stack 2 comprising a contour 14 of the portion of the structured material layer 7b adjacent to the first sub portion 21a. In particular the shell surface 8 relates to a projection of the contour 14 of the structured material layer 7b arranged on the first sub portion 21a in a vertical direction into the semiconductor layer stack or said in other words relates to a vertical extension of the contour 14 of the structured material layer 7b arranged on the first sub portions 21a into the semiconductor layer stack.

In a preferred embodiment, as shown in the lower image of FIG. 12, the structured material layer 7b/top contact element enclose an angle a with a top surface 15 of the semiconductor layer stack 2 of smaller than or equal to 90°. This can in particular mean that the structured material layer 7b/top contact element on the top surface 15 does not comprise an underetching as shown in the upper image and thus does not comprise regions distant from the top surface 15 which laterally protrude regions adjacent to the top surface. Such an underetching in particular results in an angle a with a top surface 15 of the semiconductor layer stack 2 greater than 90°.

1.-16. (canceled)

17. A method for manufacturing an optoelectronic device, the method comprising:
providing a semiconductor layer stack of at least a first layer of a first conductivity type, a second layer of a second conductivity type and an active region between the first layer and the second layer;
plasma etching the semiconductor layer stack such that a first portion of the semiconductor layer stack is retained and a second portion of the semiconductor layer stack adjacent to the first portion is removed, thereby forming a recess exposing a side surface of at least the active region of the first portion;
providing a structured material layer on the first portion covering at least one first sub portion of the first portion and leaving a second sub portion of the first portion adjacent to the at least one first sub portion exposed, wherein the at least one first sub portion is defined by an virtual shell surface extending through the semiconductor layer stack and comprising a contour of the structured material layer adjacent to the at least one first sub portion; and
providing a wet etchant into at least the recess, thereby conducting a wet chemical anisotropic etching of the first portion such that the second sub portion is removed until an imaginary shell surface and such that the at least one first sub portion is retained.

18. The method according to claim 17, wherein the second sub portion is adjacent to the recess.

19. The method according to claim 17, wherein plasma etching the semiconductor layer stack comprises injecting components of the plasma into the first portion adjacent to the recess forming a contaminated region, and wherein the contaminated region is spaced apart from the at least one first sub portion.

20. The method according to claim 17, wherein a distance between the recess and the at least one first sub portion is at least 50 nm.

21. The method according to claim 17, wherein the wet etchant comprises at least one of KOH, H₃PO₄, TMAH, H₂SO₅, NH₄OH, [NH₄]₂S, HCl, or a combination thereof.

22. The method according to claim 17, further comprising providing a material layer on the semiconductor layer stack, wherein providing the structured material layer comprises a structuring of the material layer such that the structured material layer covers the at least one first sub portion and leaves the second sub portion exposed.

23. The method according to claim 22, wherein providing the material layer is conducted before plasma etching into the semiconductor layer stack, and wherein the material layer is pre-structured by plasma etching into the semiconductor layer stack.

24. The method according to claim 17, wherein the structured material layer comprises a transparent conductive oxide or a reflective metal mirror.

25. The method according to claim 17, wherein the semiconductor layer stack is of a nitride based material system.

26. The method according to claim 17, wherein the first sub portion comprises a rectangular cross section.

27. The method according to claim 17, further comprising separating the optoelectronic device, wherein the optoelectronic device comprises the first sub portion and a portion of the structured material layer arranged on the first sub portion forming a top contact element.

28. An optoelectronic device comprising:
a semiconductor layer stack of at least a first layer of a first conductivity type, a second layer of a second conductivity type and an active region between the first layer and the second layer; and
a top contact element arranged on a top surface of the semiconductor layer stack opposite a bottom surface of the semiconductor layer stack,
wherein side surfaces of the semiconductor layer stack connecting the top surface and the bottom surface are substantially perpendicular with respect to the top surface, and
wherein the side surfaces comprise a surface roughness of less than.

29. The optoelectronic device according to claim 28, wherein the semiconductor layer stack comprises a defect density along the side surfaces that is configured to cause a current density along the side surfaces of less than or in in an order of 1e⁻⁴ A/cm² when a potential difference of −5V between the top contact element and a bottom contact element is applied or that is configured to cause a current density along the side surfaces of less than or in in an order of 1e⁻⁴ A/cm² when a potential difference of +1V between the top contact element and a bottom contact element is applied.

30. The optoelectronic device according to claim 28, wherein the semiconductor layer stack is of a nitride based material system.

31. The optoelectronic device according to claim 28, wherein the top contact element comprises a transparent conductive oxide.

32. The optoelectronic device according to claim 28, wherein the top contact element directly adjoins the top surface, and wherein side surfaces of the top contact element enclose an angle with the top surface of smaller than or equal to 90°.
